(19) United States
(12) Patent Application Publication
(10) Pub. No.: US 2016/0338193 A1
(43) Pub. Date: Nov. 17, 2016

(54) MULTILAYER BOARD AND METHOD OF MANUFACTURING MULTILAYER BOARD

(71) Applicant: FUJITSU LIMITED, Kawasaki-shi (JP)

(72) Inventors: Junichi Kanai, Nagano (JP); Yasuhiro Karahashi, Nagano (JP); Hirofumi Kobayashi, Iizuna (JP); Shunsuke KOGOI, Nagano (JP); Junichi Murayama, Nagano (JP); Koji Komemura, Nagano (JP); Hidehiko Fujisaki, Nagano (JP)

(73) Assignee: FUJITSU LIMITED, Kawasaki-shi (JP)

(21) Appl. No.: 15/099,646

(22) Filed: Apr. 15, 2016

(30) Foreign Application Priority Data
May 14, 2015 (JP) 2015-098875

(51) Int. Cl. H05K 1/02; H05K 1/11; H05K 3/00; H05K 3/46; H05K 3/06; H05K 1/09; H05K 1/03; H05K 3/40

(52) U.S. Cl. CPC H05K 1/0298; H05K 1/0313; H05K 1/115; H05K 3/4069; H05K 3/4652; H05K 3/064; H05K 1/09; H05K 3/0038; H05K 2201/015; H05K 2201/0141

(57) ABSTRACT

A multilayer board disclosed herein includes: a plurality of insulating layers made of a thermosetting resin and stacked on one another, each insulating layer being provided with a via hole; a plurality of wiring each formed between the insulating layers and including an inclined side surface; and a conductive via made of a cured product of conductive paste filled in the via hole and connecting the vertically adjacent wiring to each other. Here, orientations of the inclined side surfaces are alternately changed from the wiring to the wiring.

### CROSS-REFERENCE TO RELATED APPLICATION

This application is based upon and claims the benefit of priority of the prior Japanese Patent Application No. 2015-98875, filed on May 14, 2015, the entire contents of which are incorporated herein by reference.

### FIELD

The embodiments discussed herein are related to a multilayer board and a method of manufacturing a multilayer board.

### BACKGROUND

With the advance of information processing techniques, developments of multilayer boards in smaller sizes and with higher performances for use in electronic equipment such as servers are now in progress. A typical multilayer board is formed by alternately stacking insulating layers and wiring layers. The vertically adjacent wiring layers are connected to each other by use of conductive vias.

Methods of manufacturing such a multilayer board include a bonding method, a build-up method, and so forth. In any case, however, the wiring and the conductive vias are formed by a plating process. Though the plating process has been well established from a technical perspective, this process needs several hours for forming each wiring layer, thus leading to prolonged production time of the multilayer board. Further, the plating process also has a problem of environmental pollution caused by disposal of a waste plating solution.

To avoid these problems, there are proposed methods of forming wiring and conductive vias without using the plating process.

One of the proposed methods is a method of forming a conductive via by using conductive paste. This method is designed to form the conductive via by filling a via hole in an insulating layer with the conductive paste, and therefore does not use the plating process for forming the conductive via.

Moreover, in order to form wiring on the conductive via, it is preferably to pattern a copper foil on the insulating layer. Accordingly, the plating process is not used for forming the wiring.

It is to be noted that techniques related to this application are disclosed in Japanese Laid-open Patent Publications No. 11-204942 and No. 2009-152496.

### SUMMARY

According to one perspective of a following disclosure, a multilayer board includes: a plurality of insulating layers made of a thermosetting resin and stacked on one another, each insulating layer being provided with a via hole; a plurality of wiring each formed between the insulating layers and including an inclined side surface; and a conductive via made of a cured product of conductive paste filled in the via hole and connecting the vertically adjacent wiring to each other. Here, orientations of the inclined side surfaces are alternately changed from the wiring to the wiring.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIGS. 1A to 1F are cross-sectional views of a multilayer board in the course of manufacturing the same without using a plating process.

FIGS. 2A to 2R are cross-sectional views of a multilayer board in the course of manufacturing the same according to an embodiment.

FIGS. 3A and 3B are cross-sectional views of a multilayer board in the course of manufacturing the same according to another embodiment.

### DESCRIPTION OF EMBODIMENTS

Matters considered by the inventor of this application will be described prior to description of embodiments.

As mentioned previously, in order to reduce production time of a multilayer board and to prevent environmental pollution, it is desired to manufacture wiring and conductive vias without using a plating process.

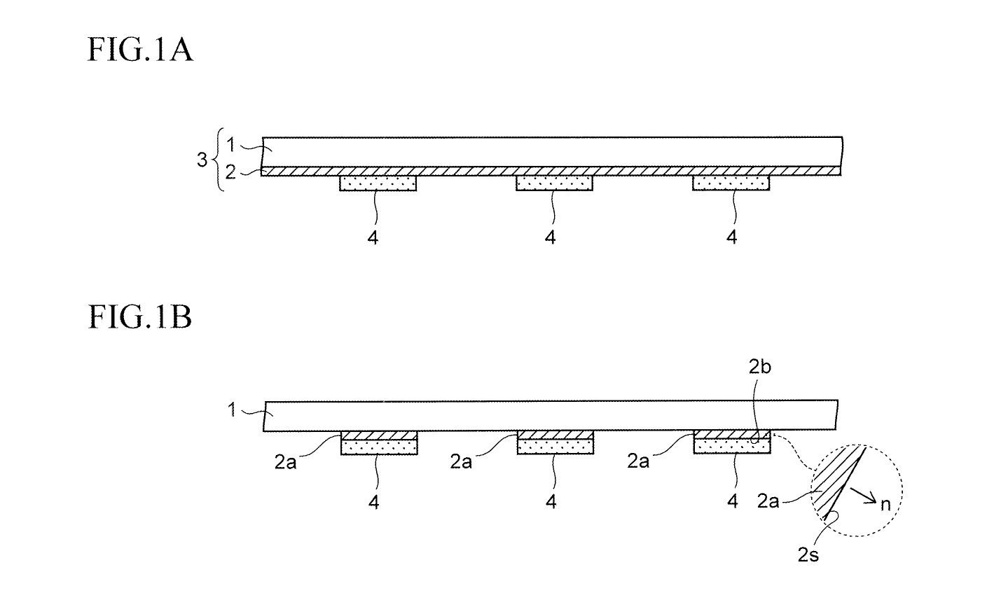

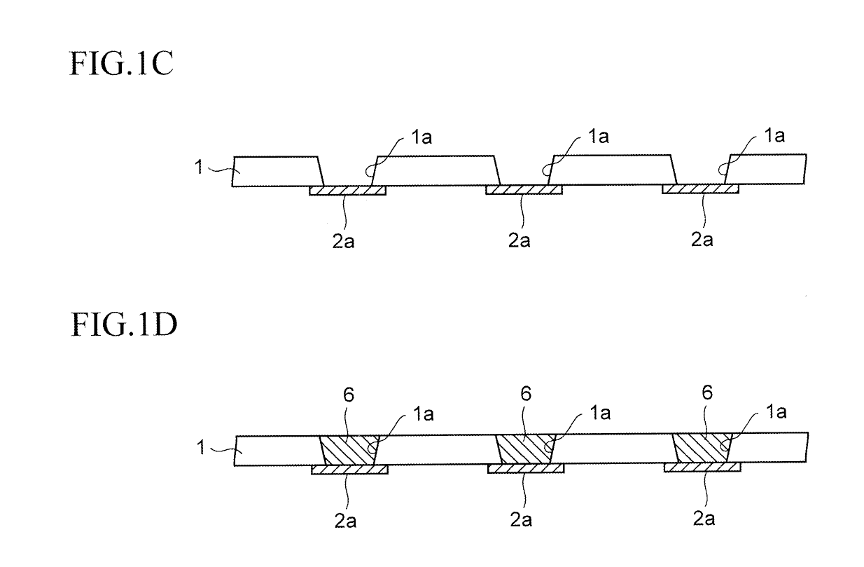

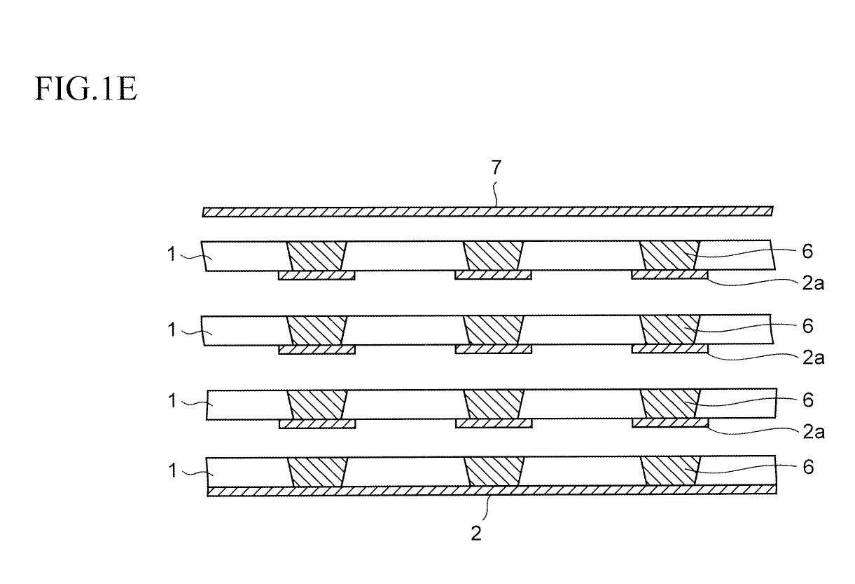

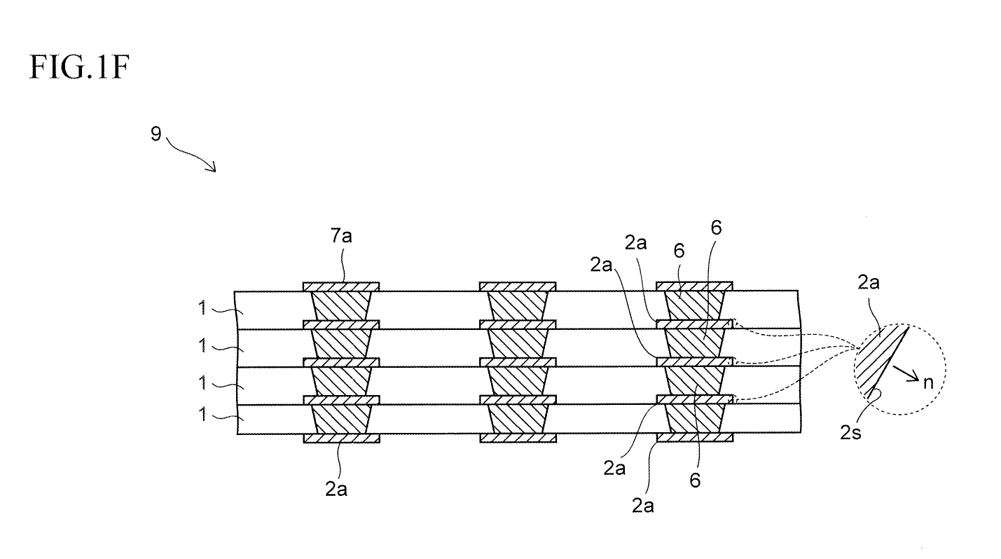

FIGS. 1A to 1F are cross-sectional views of a multilayer board in the course of manufacturing the same without using a plating process.

To manufacture the multilayer board, a single-sided copper-clad base material 3 is first prepared by attaching a copper foil 2 onto one of principal surfaces of an insulating layer 1 as illustrated in FIG. 1A. The insulating layer 1 is made of a thermoplastic resin. In this example, a liquid crystal polymer is used as the thermoplastic resin.

Then, dry film resist 4 in the shape of wiring is attached onto the copper foil 2.

Next, as illustrated in FIG. 1B, wiring 2a is formed by wet etching the copper foil 2 while using the dry film resist 4 as a mask.

Since the wet etching progresses isotropically, each side surface 2s of the wiring 2a is inclined as illustrated in a dotted circle. In particular, the etching progresses laterally at a portion near a surface 2b of the wiring 2a to be exposed to an etchant for a longer period. As a consequence, a direction n of a normal line of the side surface 2s is directed obliquely downward.

After the wet etching is completed, the dry film resist 4 is peeled off.

Subsequently, as illustrated in FIG. 1C, via holes 1a are formed in the insulating layer 1 on the wiring 2a by evaporating the insulating layer 1 by laser beam irradiation. In this example, each via hole 1a is formed into a bottomed shape since a lower open end of the via hole 1a is closed with the wiring 2a.

Next, a process illustrated in FIG. 1D will be described.

First, each via hole 1a is filled with metal powder which is prepared by blending copper powder, tin powder, and bismuth powder. Here, the metal powder does not contain any binder. Accordingly, the metal powder takes the form of non-viscous powder.

As described above, since the via holes 1a are bottomed in this example, it is possible to prevent the metal powder from running down the via holes 1a without having to provide a special jig for closing the bottoms of the via holes 1a.

Thereafter, conductive vias 6 are formed by heating and alloying the metal powder.

Subsequently, as illustrated in FIG. 1E, some insulating layers 1 are stacked in such a way that the insulating layers 1 and the wiring 2a are alternately arranged.

Here, the copper foil 2 is formed on the entire surface of the lowermost insulating layer 1 by omitting the process of FIG. 1B. Meanwhile, a copper foil 7 is superposed on the upper most insulating layer 1.

Then, as illustrated in FIG. 1F, the insulating layers 1 using of the thermoplastic resin as the material are softened by heating the insulating layers 1 to its softening temperature or above. Next, the insulating layers 1 in this state are pressed together. Thus, the insulating layers 1 are pressure bonded to and integrated with one another.

Thereafter, the copper foils 2 and 7 are patterned by wet etching and are thus formed into wiring 2a and 7a.

Thus, a basic structure of a multilayer board 9 of this example is obtained.

In this example, since each side surface 2s of the wiring 2a between the insulating layers 1 is inclined due to the process of FIG. 1B, all the directions n of the normal lines of the side surfaces 2s are directed to the same direction irrespective of which layer the wiring 2a belongs to.

Meanwhile, in the above-described method of manufacturing the multilayer board 9, the plating process is not used for forming the wiring 2a or the conductive vias 6. For this reason, as compared to the case of using the plating process, this method may reduce time for forming the wiring 2a and the conductive vias 6, and also prevent environmental pollution caused by disposal of a plating solution.

Moreover, since the via holes 1a are formed into the bottomed shape, it is possible to prevent the metal powder to form the conductive vias 6 from running down the via holes 1a in the process of FIG. 1D without having to use a special jig for closing the bottoms of the via holes 1a. Thus, the manufacturing cost equivalent to such a jig may be reduced.

Furthermore, since the thermoplastic resin is adopted as the material for the insulating layers 1, it is possible to soften and simultaneously integrate the insulating layers 1 together by the heating as illustrated in FIG. 1F.

However, the thermoplastic resin tends to have a high dielectric constant and is therefore disadvantageous for speeding up signals flowing on the wiring 2a. For example, a dielectric loss tangent of the liquid crystal polymer used as the material for the insulating layers 1 in this example is as high as about 0.003, which makes it difficult to speed up the signals.

Moreover, in this method, the wiring 2a is formed on one of the principal surfaces of each insulating layer 1 in the process of FIG. 1A. In order to shorten the manufacturing process, it may be effective to form the wiring 2a simultaneously on two surfaces of each insulating layer 1a. In this case, however, the laser beam emitted from above in the process of FIG. 1C is blocked by the wiring 2a. For this reason, if the wiring 2a is formed simultaneously on the two surfaces, the via holes 1a are not formed.

Now, an embodiment of the invention will be described below.

### Embodiment

In this embodiment, the following measures take place to speed up signals flowing on wiring of a multilayer board.

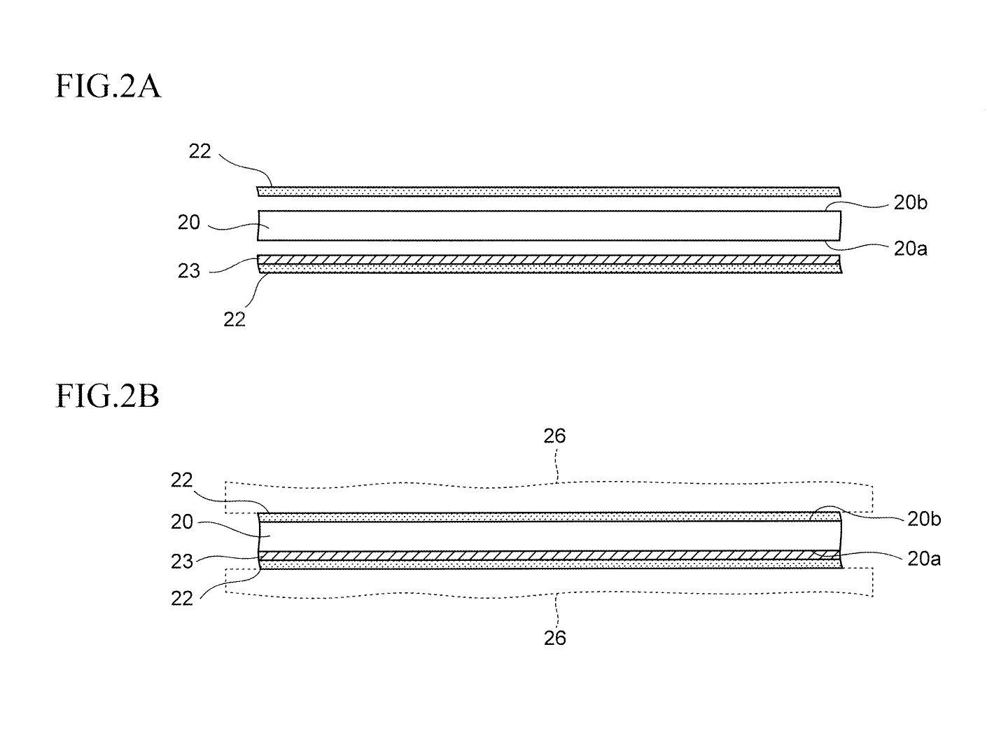

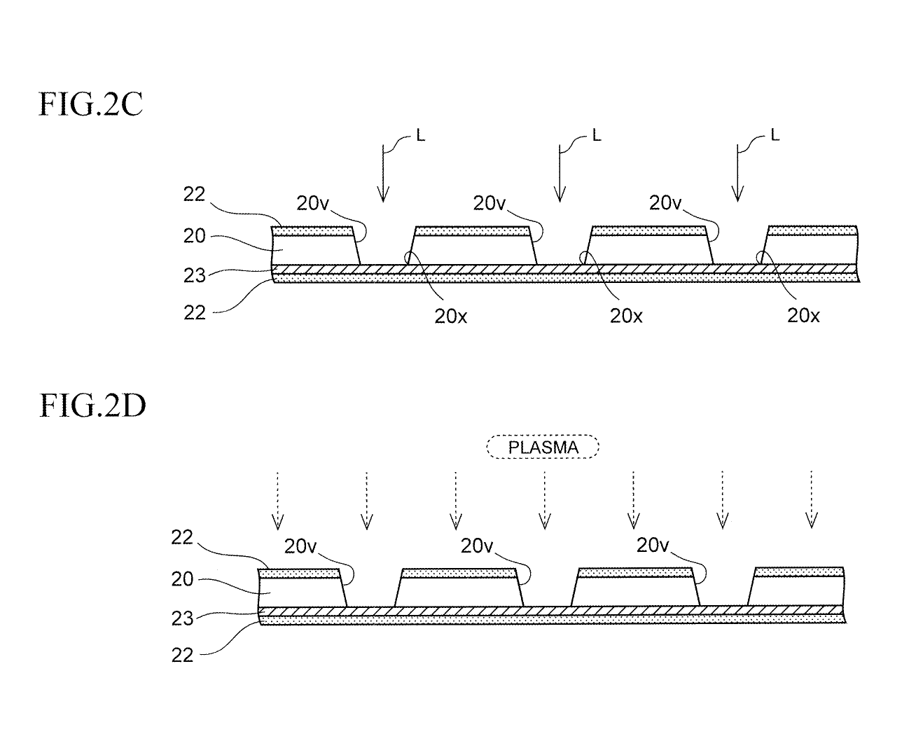

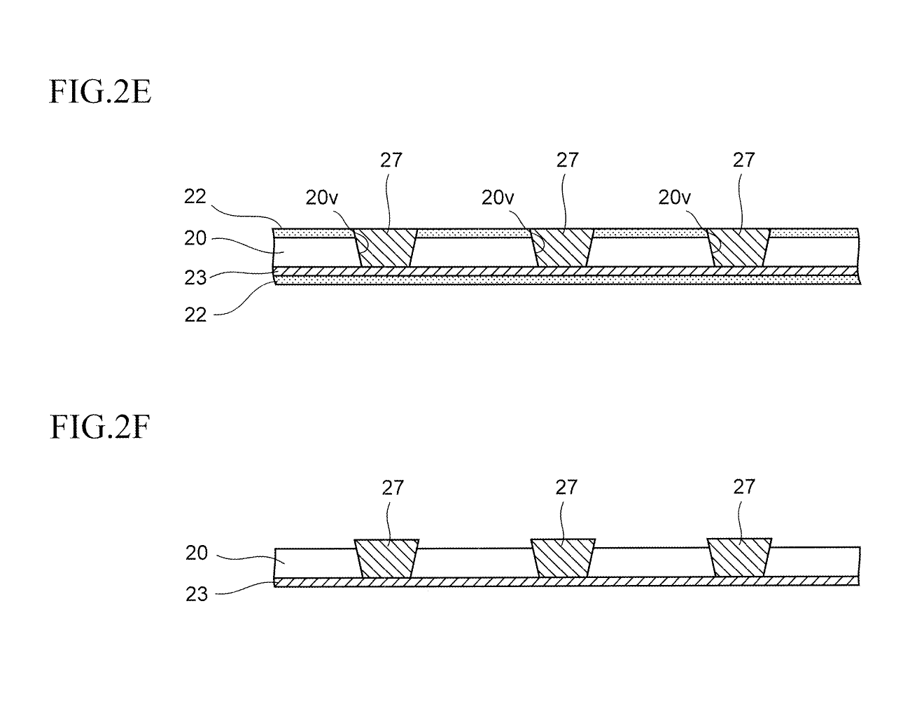

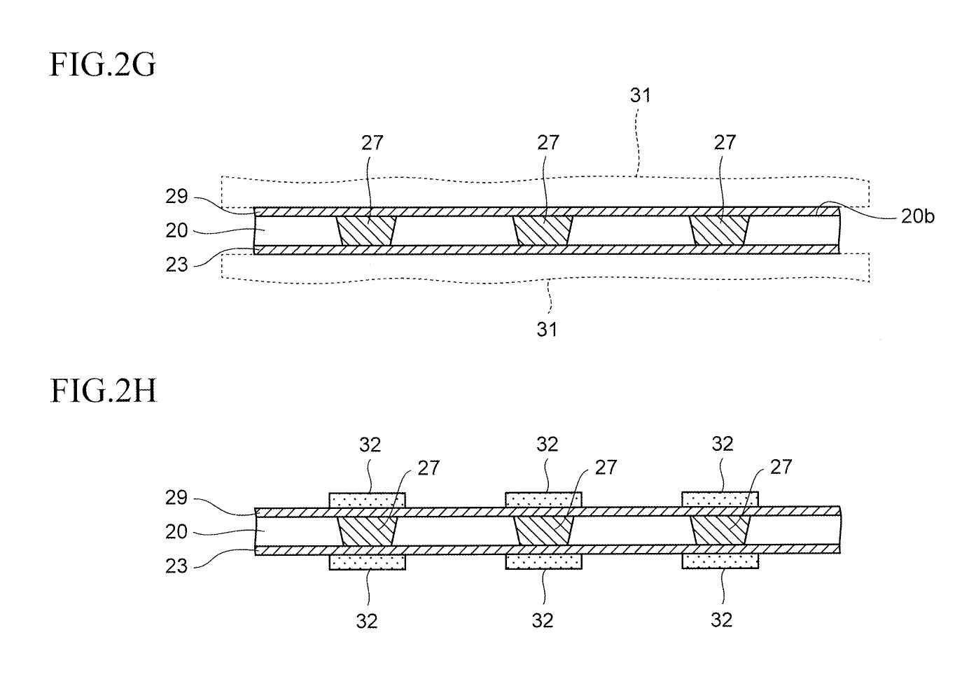

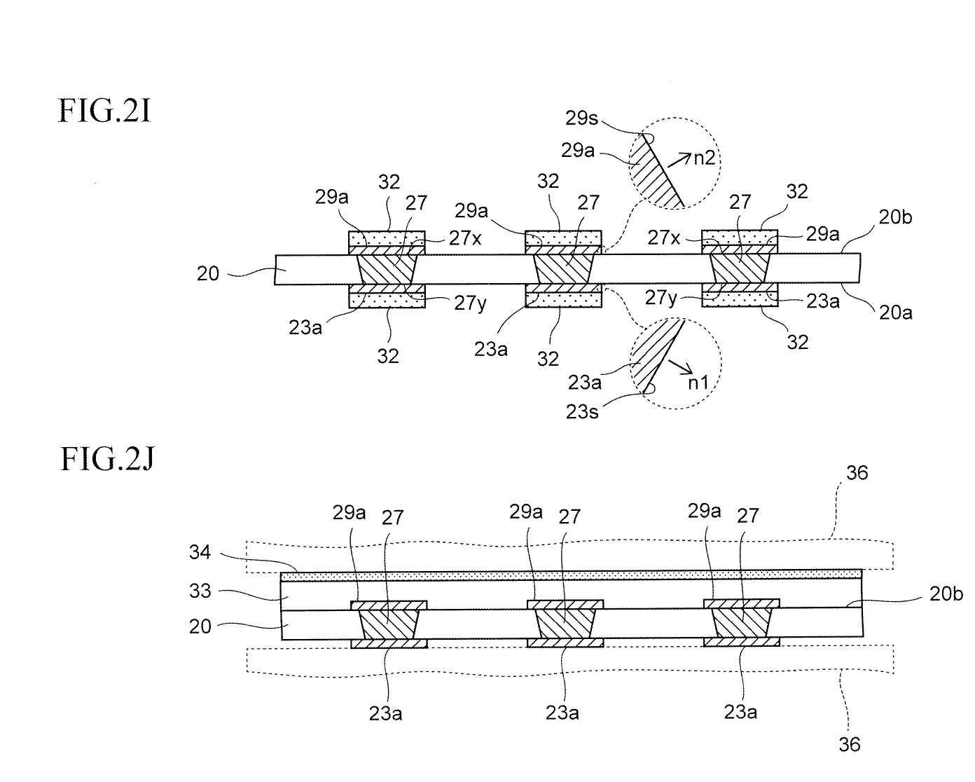

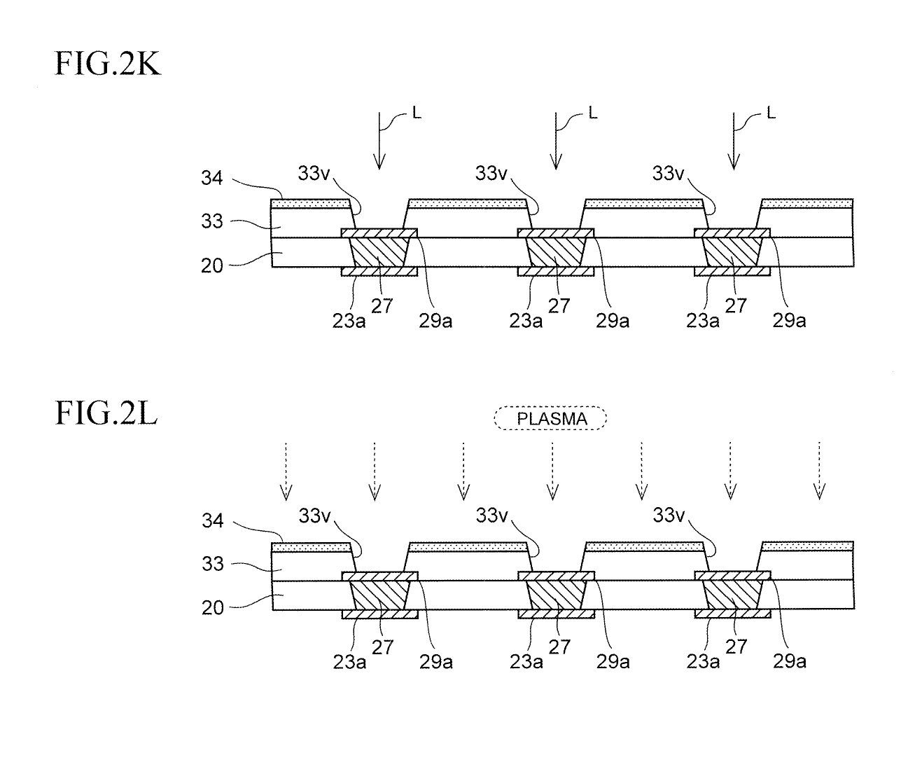

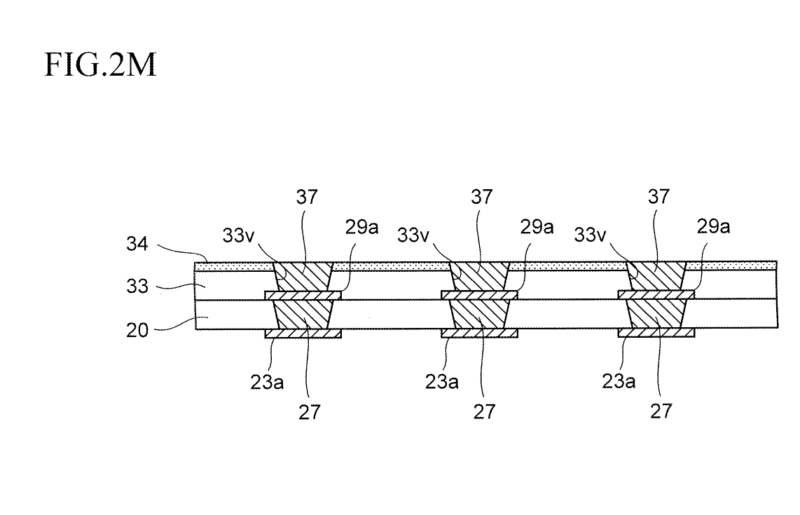

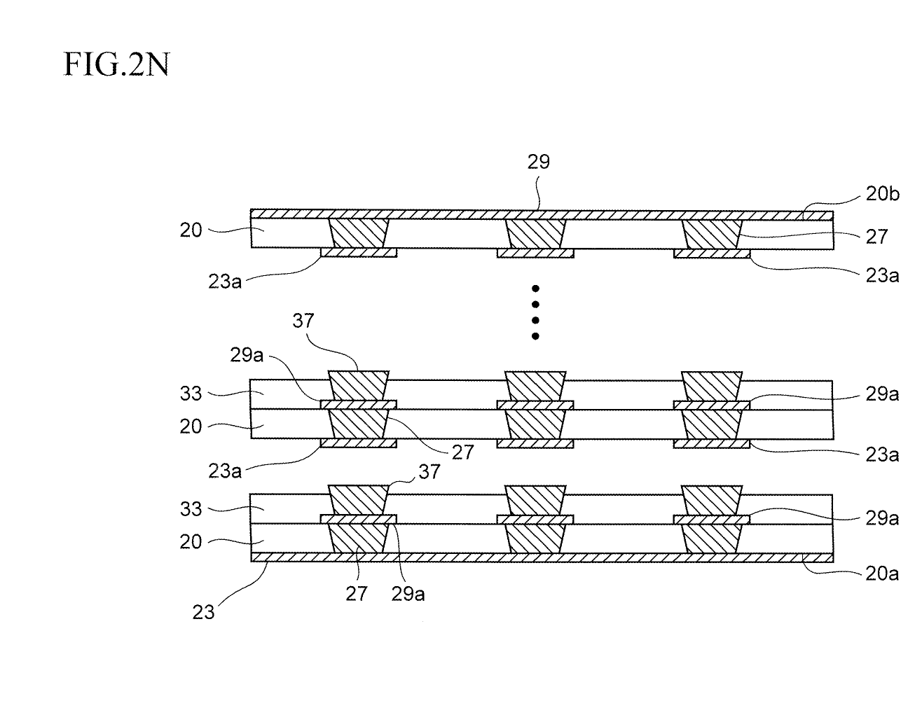

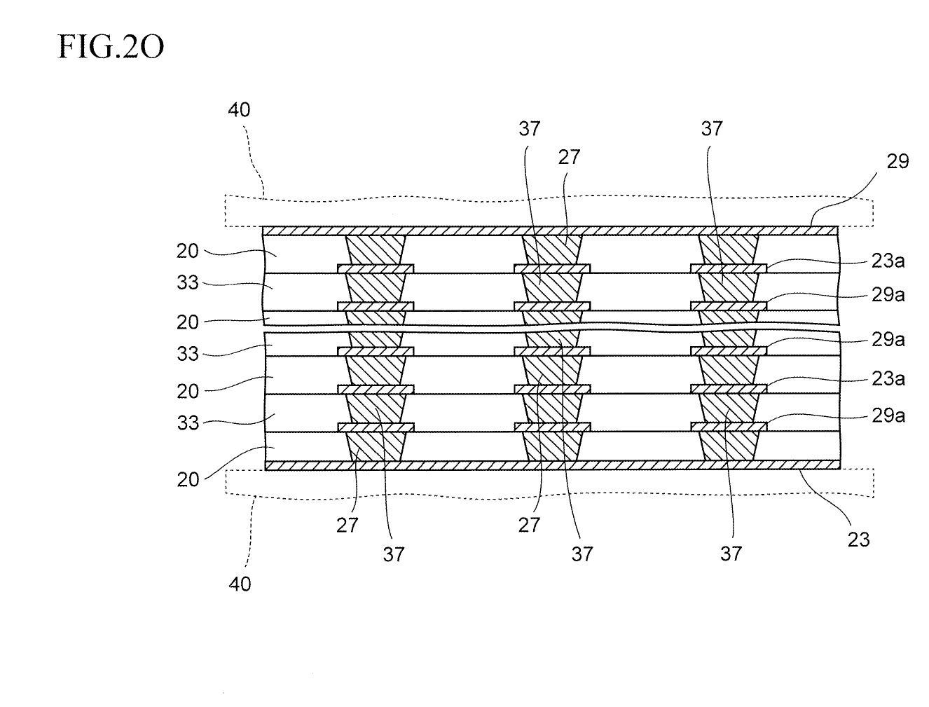

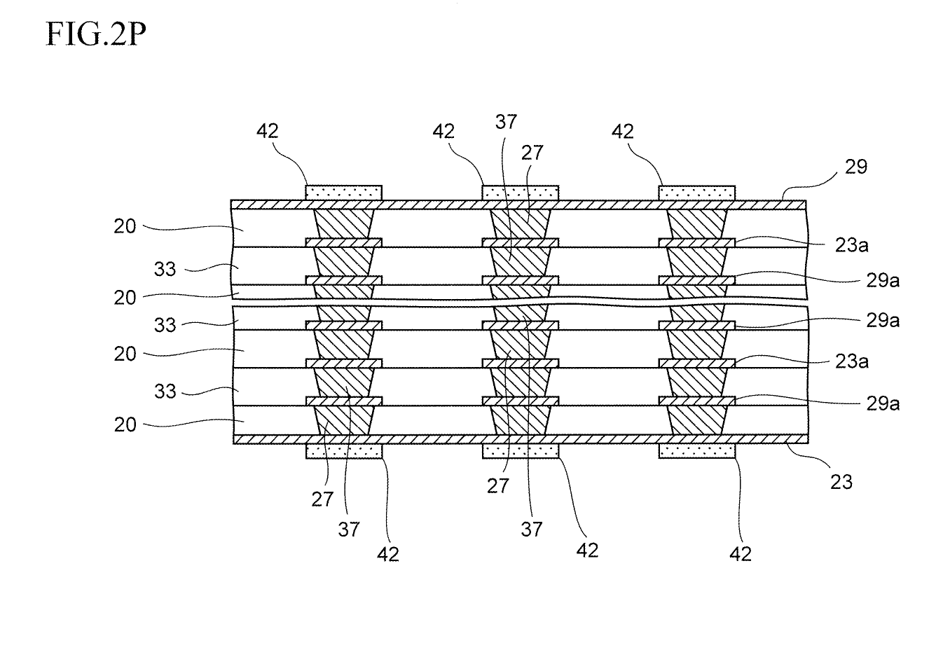

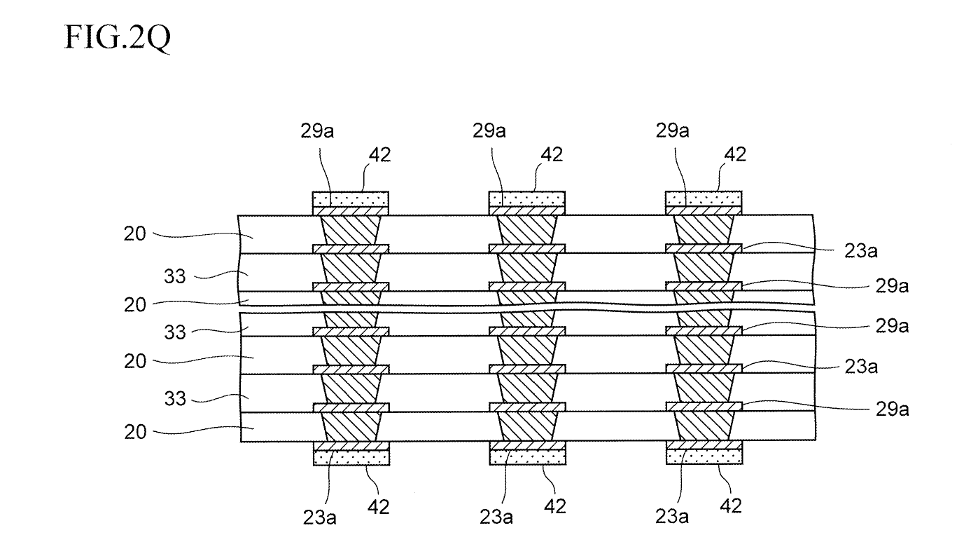

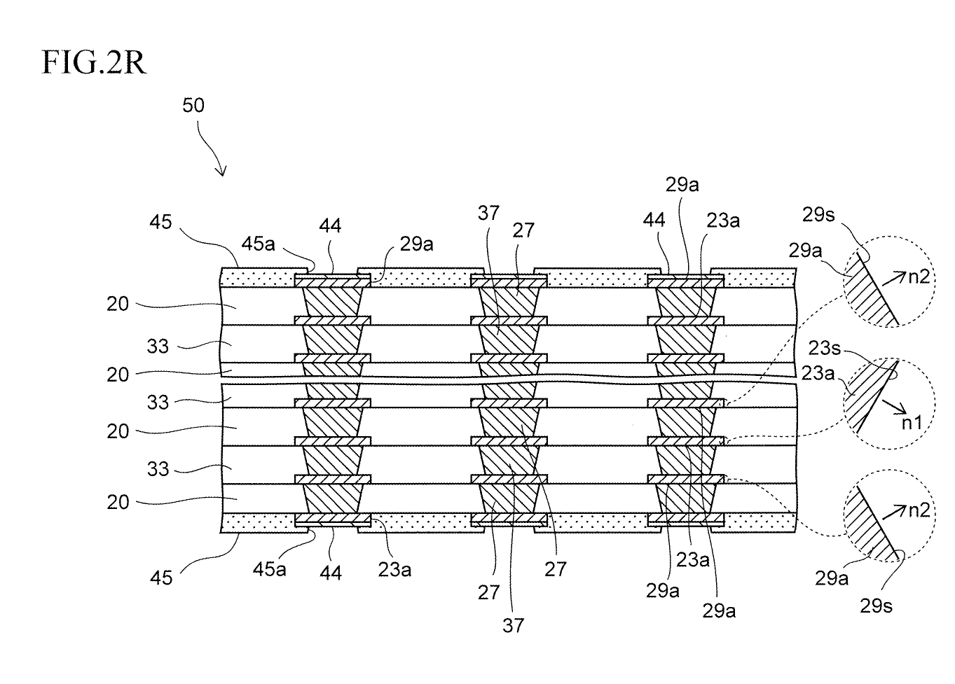

FIGS. 2A to 2R are cross-sectional views of a multilayer board in the course of manufacturing the same according to the embodiment.

First, as illustrated in FIG. 2A, an uncured thermosetting resin sheet is prepared as a first insulating layer 20. This uncured resin sheet is also called a prepreg.

A thermosetting resin having a lower dielectric loss tangent than that of the thermoplastic resin is available. Such a thermosetting resin is advantageous for speeding up signals flowing on wiring. In this embodiment, epoxy resin having a dielectric loss tangent of about 0.002 is used as the thermosetting resin.

Various additives may be added to the epoxy resin in accordance with electrical characteristics such as the dielectric constant needed in the first insulating layer 20. For example, the dielectric constant of the first insulating layer 20 is further reduced by adding Teflon (registered trademark) to the epoxy resin. Thus, it is possible to further speed up the signals.

Meanwhile, polyphenylene oxide (PPO) or the like may be added to the epoxy resin.

Although a thickness of the first insulating layer 20 is not limited to a particular thickness, the thickness is set in this example in a range from about 30 μm to 100 μm, for instance.

Then, a first metal foil 23 provided with a protection film 22 is disposed on one principal surface 20a side of the first insulating layer 20. The first metal foil 23 is a copper foil, for instance, and has a thickness in a range from about 12 μm to 35 μm.

The protection film 22 has a function to prevent the powdery epoxy resin from scattering from the uncured first insulating layer 20, and also serves as a substitute for a printing plate for filling conductive paste in a later process. Another protection film 22 is provided on the other principal surface 20b side of the first insulating layer 20. In this example, a PET (polyethylene terephthalate) film having a thickness in a range from about 12 μm to 50 μm is used as the protection film 22.

Next, as illustrated in FIG. 2B, the first insulating layer 20, the protection films 22, and the first metal foil 23 are stacked on one another and are then clamped in a vacuum with a jig 26.

Thereafter, the first insulating layer 20 is heated with a not-illustrated heater built in the jig 26 while applying a pressure of about 5 kg/cm² from the jig 26 to the first insulating layer 20.

The heating temperature is set to about 130° C. which is lower than a temperature to bring about complete cross-link of the first insulating layer 20.

By setting the temperature as mentioned above, it is possible to slightly cure the principal surfaces 20a and 20b while leaving the major part of the first insulating layer 20 uncured, and thus to pressure bond the first metal foil 23 and the protection films 22 to the principal surfaces 20a and 20b. Note that the above-described state of the first insulating layer 20 in which the principal surfaces 20a and 20b are cured while the major part of the first insulating layer 20 is left uncured will be hereinafter also referred to as a semi-cured state.

Next, as illustrated in FIG. 2C, one of the protection films 22 and the first insulating layer 20 are irradiated with a laser beam L, respectively. Thus, a plurality of via holes 20v each having a diameter of about 150 μm are formed by evaporating the protection film 22 and the first insulating layer 20.

As an oscillator of the laser beam L, an oscillator of YAG laser or CO₂ laser is available, for example. Moreover, an output of the laser beam L is set to such an intensity which does not cause an opening in the first metal foil 23. As a consequence, one open end 20x of each via hole 20v is closed with the first metal foil 23.

Subsequently, as illustrated in FIG. 2D, inner surfaces of the via holes 20v are exposed to a plasma atmosphere generated from a mixed gas of CF₄ gas and O₂ gas. Thus, residues of the first insulating layer 20 adhering to the inner surfaces of the via holes 20v at the time of formation thereof are removed.

The above-described process for removing the residues is called desmearing.

In this embodiment, since the first insulating layer 20 is in the uncured state as described above, the residues are also in the uncured state which may be easily removed. For this reason, the residues may be removed by conducting a dry process as described above without using an alkaline solution for removing hard residues which are completely thermally cured. As a consequence, it is possible to prevent environmental pollution by the alkaline solution.

Next, as illustrated in FIG. 2E, the via holes 20v are filled with conductive paste by a printing method, and conductive vias 27 are thus formed.

The material for the conductive vias 27 is not limited to a particular material. In this embodiment, the conductive paste for the conductive vias 27 is prepared by kneading the uncured thermosetting resin, copper powder, tin powder, and bismuth powder together.

Meanwhile, the thermosetting resin for the conductive vias 27 is not limited to a particular resin. In this embodiment, thermosetting epoxy resin which is the same as that for the first insulating layer 20 is adopted as the aforementioned thermosetting resin. Thus, the conductive vias 27 stick well to the first insulating layer 20, whereby the conductive vias 27 are less likely to be peeled off the first insulating layer 20.

Furthermore, since the via holes 20v are bottomed, it is possible to prevent the conductive vias 27 in the form of the paste from leaking out of the via holes 20v without having to use a special jig for closing the bottoms of the via holes 20v.

Thereafter, as illustrated in FIG. 2F, the protection films 22 are peeled off the surfaces of the first insulating layer 20 and the first metal foil 23, respectively.

Here, the epoxy resin in the conductive vias 27 is not yet thermally cured and is therefore in the form of the paste.

Subsequently, as illustrated in FIG. 2G, a copper foil having a thickness in a range from about 12 μm to 35 μm and serving as a second metal foil 29 is placed on the other principal surface 20b of the first insulating layer 20.

Then, the first metal foil 23, the first insulating layer 20, and the second metal foil 29 are clamped in a vacuum with a jig 31, and the first insulating layer 20 is heated with a not-illustrated heater built in the jig 31 while applying a pressure of about 30 kg/cm² to the first insulating layer 20.

The heating temperature is set to about 200° C. which is a temperature to bring about complete cross-link of the first insulating layer 20. Thus, the first insulating layer 20 is thermally cured.

Meanwhile, since the thermosetting resin is used as the material for the conductive vias 27 in this embodiment as described above, the conductive vias 27 may also be thermally cured simultaneously with the thermal curing of the first insulating layer 20. Thus, it is possible to omit a process of thermally curing the conductive vias 27 alone.

When the conductive vias 27 are thermally cured by the heating as described above, the materials included in the conductive vias 27, namely, the copper powder, the tin powder, and the bismuth powder are alloyed. Accordingly, the conductive vias 27 are formed of a cured product which includes the alloy of these materials, and the thermosetting resin.

Thereafter, as illustrated in FIG. 2H, dry film resist 32 in the shape of the wiring is attached to each of the first metal foil 23 and the second metal foil 29.

Then, as illustrated in FIG. 2I, the first metal foil 23 and the second metal foil 29 are simultaneously subjected to wet etching while using the dry film resist 32 as masks, and are thereby formed into wiring 23a and 29a.

According to this method, the wiring 23a and 29a may be formed simultaneously on the principal surfaces 20a and 20b of the first insulating layer 20, respectively. Thus, it is possible to reduce the number of processes as compared to a case of forming the wiring 23a and the wiring 29a separately.

Here, if it is not important to reduce the number of processes, then the metal foil may be left on the entire surface of any of the principal surfaces 20a and 20b of the first insulating layer 20 by forming the dry film resist 32 on the entire surface of any of the first metal foil 23 and the second metal foil 29.

In the meantime, since the wet etching progresses isotropically, each of side surfaces 23s and 29s of the wiring 23a and 29a is inclined with respect to the corresponding principal surface 20a or 20b as illustrated in dotted circles. Directions of inclination are different between the cases of the wiring 23a and the wiring 29a. For example, a direction n1 of a normal line of each side surface 23s is directed obliquely downward in the case of the wiring 23a exposed to an etchant from below, whereas a direction n2 of a normal line of each side surface 29s is directed obliquely upward in the case of the wiring 29a exposed to the etchant from above.

Meanwhile, the wiring 23a is connected to the wiring 29a by using the conductive vias 27. Here, the upper wiring 29a is in contact with entire surfaces of upper surfaces 27x of the conductive vias 27. Accordingly, it is possible to reduce resistance between each conductive via 27 and the wiring 29a. Likewise, since the lower wiring 23a is in contact with entire surfaces of lower surfaces 27y of the conductive vias 27, it is possible to reduce resistance between each conductive via 27 and the wiring 23a as well.

After the wet etching is completed, the dry film resist 32 is peeled off.

Next, a process illustrated in FIG. 2J will be described.

First, a second insulating layer 33 and a protection film 34 are stacked in this order on the other principal surface 20b of the first insulating layer 20.

The second insulating layer 33 is an uncured thermosetting resin sheet having a thickness in a range from about 30 μm to 100 μm. In this example, the epoxy resin having the same thermosetting property as that of the first insulating layer 20 is used as the material for the second insulating layer 33.

Meanwhile, the protection film 34 has a function to prevent the powdery epoxy resin from scattering from the uncured second insulating layer 33, and also serves as a substitute for a printing plate for filling conductive paste in a later process. The protection film 34 is a PET film having a thickness in a range from about 12 μm to 50 μm, for example.

Then, the second insulating layer 33 is heated with a not-illustrated heater built in a jig 36 while applying a pressure of about 5 kg/cm² from the jig 36 to the second insulating layer 33. Thus, the second insulating layer 33 is semi-cured, and the first insulating layer 20 and the protection film 34 are pressure bonded to two surfaces of the second insulating layer 33, respectively.

Next, as illustrated in FIG. 2K, the second insulating layer 33 and the protection film 34 are irradiated with the laser beam L, respectively. Thus, a plurality of via holes 33v each having a diameter of about 150 are formed by evaporating the protection film 34 and the second insulating layer 33. The wiring 29a is exposed from the via holes 33v.

As with the process of FIG. 2C, as the oscillator of the laser beam L, an oscillator of YAG laser or CO₂ laser is available, for example. Moreover, an output of the laser beam L is set to such an intensity which does not cause an opening in the wiring 29a.

Subsequently, as illustrated in FIG. 2L, inner surfaces of the via holes 33v are exposed to the plasma atmosphere generated from the mixed gas of CF₄ gas and O₂ gas in order to perform desmearing of the via holes 33v. Thus, residues of the second insulating layer 33 adhering to the inner surfaces of the via holes 33v at the time of formation thereof are removed.

As with the process of FIG. 2D, the residues originated from the semi-cured second insulating layer 33 are easily removable. Accordingly, it is possible to remove the residues by conducting the dry process as described above without using an alkaline solution which would cause environmental pollution.

Next, as illustrated in FIG. 2M, the via holes 33v are filled with conductive paste by the printing method, and conductive vias 37 are thus formed. This conductive paste is the same as the one used for forming the conductive vias 27, which may be prepared by kneading the uncured thermosetting resin, the copper powder, the tin powder, and the bismuth powder together.

Thereafter, the protection film 34 is peeled off the second insulating layer 33.

Next, as illustrated in FIG. 2N, a plurality of the first insulating layers 20 having undergone the aforementioned processes are prepared, and the first insulating layers 20 and the semi-cured second insulating layers 33 are alternately stacked.

Although the number of stacked layers is not limited to a particular value, the total number of the stacked layers of the first insulating layers 20 and the second insulating layers 33 is set in a range from ten layers to seventy layers in this embodiment.

Here, regarding the lowermost first insulating layer 20, the first metal foil 23 is left on the entire principal surface 20a of the first insulating layer 20 without etching the first metal foil 23 in the process of FIG. 2I.

Moreover, regarding the uppermost first insulating layer 20, the second metal foil 29 is left on the entire principal surface 20b of the first insulating layer 20 without etching the second metal foil 29 in the process of FIG. 2I, and the second insulating layer 33 is not formed on the second metal foil 29.

Next, as illustrated in FIG. 2O, the first insulating layers 20 are aligned with one another and then the insulating layers 20 and 33 are clamped in a vacuum with a jig 40. A method of aligning the first insulating layers 20 is not limited to a particular method. The alignment method includes: pin lamination designed to achieve alignment by forming common openings in the first insulating layers 20, respectively, and inserting a pin into the openings; and mass lamination designed to achieve alignment by aligning edges on a particular side of the first insulating layers 20 with one another.

Then, the second insulating layers 33 are heated to a temperature of about 200° C. with a not-illustrated heater built in the jig 40 while applying a pressure of about 30 kg/cm² from the jig 40 to the first insulating layers 20 and the second insulating layers 33.

Thus, each of the second insulating layers 33 is completely thermally cured, and the second insulating layers 33 and the first insulating layers 20 are pressure bonded to one another. Further, each wiring 23a and the corresponding wiring 29a are connected to each other through the conductive vias 37.

At this time, the first metal foil 23 and the second metal foil 29 are formed on the entire surfaces of the lowermost and uppermost first insulating layers 20, respectively. Thus, the pressure from the jig 40 may be evenly applied to the respective first insulating layers 20 via the metal foils 23 and 29.

Subsequently, as illustrated in FIG. 2P, dry film resist 42 in the shape of wiring is attached onto each of the lowermost first metal foil 23 and the uppermost second metal foil 29.

Then, as illustrated in FIG. 2Q, the first metal foil 23 and the second metal foil 29 are simultaneously subjected to wet etching while using the dry film resist 42 as masks, and are thus formed into the wiring 23a and 29a.

Next, as illustrated in FIG. 2R, a gold-plated layer 44 is formed on each of surfaces of the uppermost wiring 29a and the lowermost wiring 23a in order to improve solder wettability. Then, solder resist 45 is coated on the surfaces of the uppermost and lowermost first insulating layers 20 by the printing method.

Openings 45a are formed in the solder resist 45 on the wiring 23a and 29a, and solder bumps are bonded to the wiring 23a and 29a in the openings 45a in a later process.

Thus, a basic structure of a multilayer board 50 of this embodiment is finished.

In the multilayer board 50, the wiring 23a and 29a is formed simultaneously on the two surfaces of each first insulating layer 20. Accordingly, the directions n1 and n2 of the normal lines of the side surfaces 23s and 29s of the wiring are directed obliquely downward and obliquely upward, respectively. As a consequence, orientations of the side surfaces 23s and 29s of the wiring 23a and 29a are alternately changed.

Meanwhile, according to the above-described embodiment, the plating process is not used for forming the wiring 23a and 29a and the conductive vias 27 and 37. Thus, it is possible to reduce the production time of the multilayer board 50 as compared to the case of using the plating process. In addition, this embodiment does not generate a waste plating solution which would cause environmental pollution.

Furthermore, the thermosetting resin is adopted as the material for the first insulating layers 20 and the second insulating layers 33 of the multilayer board 50. As the thermoplastic resin used therein, a thermosetting resin such as a liquid crystal polymer having a lower dielectric loss tangent than that of a thermoplastic resin is available. Thus, it is possible to speed up signals flowing on the wiring 23a and 29a.

In addition, since the wiring 23a and 29a is formed simultaneously on the two principal surfaces 20a and 20b of each first insulating layer 20 in the process of FIG. 2I, it is possible to reduce the number of processes as compared to the case of forming the wiring 23a and the wiring 29a, respectively, in the separate processes.

### Another Embodiment

In the above-described embodiment, the first insulating layers 20 each provided with the two layers of the wiring 23a and 29a are stacked on one another. As a consequence, the multilayer board 50 includes an even number of layers of the wiring 23a and 29a.

In contrast, this embodiment is configured to manufacture a multilayer board having an odd number of wiring layers as described below.

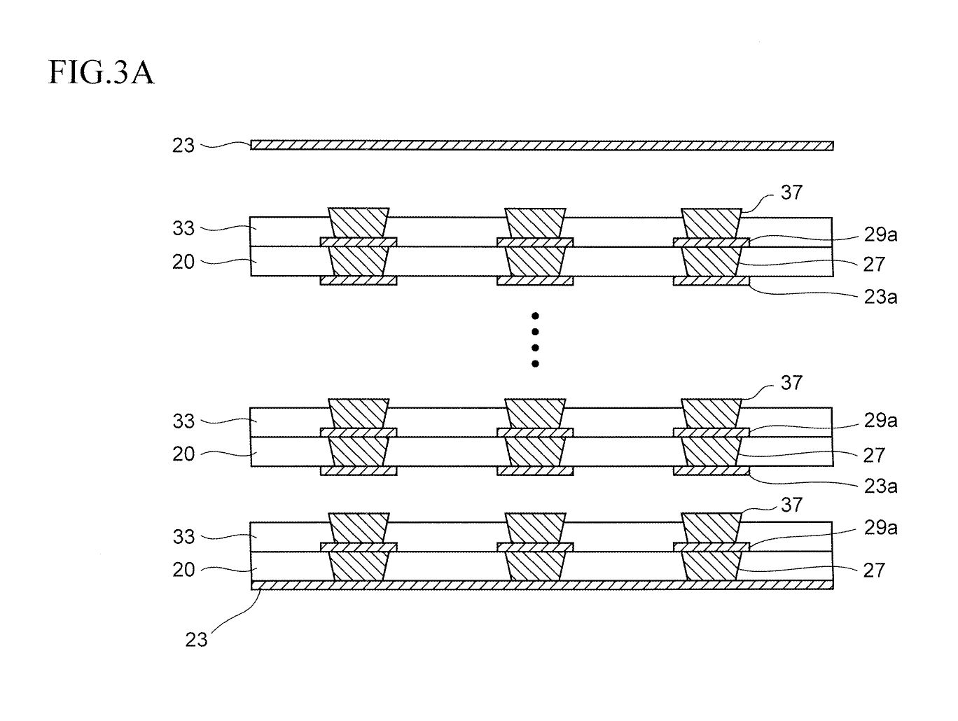

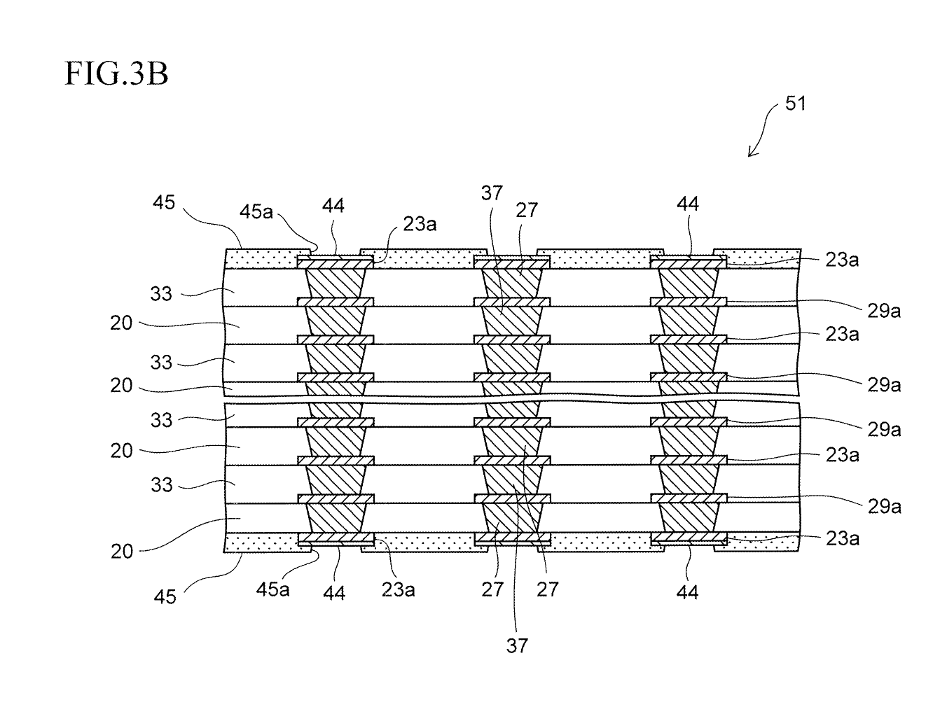

FIGS. 3A and 3B are cross-sectional views of a multilayer board in the course of manufacturing the same according to this embodiment.

To form an odd number of wiring layers, a cross-sectional structure illustrated in FIG. 3A is first obtained by performing the processes of FIGS. 2A to 2N in accordance with the original embodiment.

However, in this embodiment, the wiring 29a and the second insulating layer 33 are formed on the uppermost first insulating layer 20, and an additional first metal foil 23 is provided on the aforementioned second insulating layer 33.

Thereafter, a basic structure of a multilayer board 51 of this embodiment illustrated in FIG. 3B is obtained by performing the processes of FIGS. 20 to 2R.

By providing the additional first metal foil 23 on the uppermost layer as illustrated in FIG. 3A, the number of layers of the wiring 23a and 29a is increased by one and becomes an odd number.

Accordingly, it is possible to supply not only the multilayer board including the even number of layers of the wiring 23a and 29a but also the multilayer board including the odd number of layers of the wiring. Thus, it is possible to respond to a need of a customer who uses an odd number of the wiring layers.

All examples and conditional language recited herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A multilayer board comprising:
a plurality of insulating layers made of a thermosetting resin and stacked on one another, each insulating layer being provided with a via hole;
a plurality of wiring each formed between the insulating layers, and each including an inclined side surface; and
a conductive via made of a cured product of conductive paste filled in the via hole and connecting the vertically adjacent wiring to each other, wherein
orientations of the inclined side surfaces are alternately changed from the wiring to the wiring.

2. The multilayer board according to claim 1, wherein the cured product contains the same thermosetting resin as the thermosetting resin in the insulating layer.

3. The multilayer board according to claim 2, wherein the thermosetting resin is epoxy resin containing Teflon (registered trademark).

4. The multilayer board according to claim 1, wherein
of the vertically adjacent wiring, the wiring located on a lower side is in contact with an entire lower surface of the conductive via, and the wiring located on an upper side is in contact with an entire upper surface of the conductive via.

5. A method of manufacturing a multilayer board, the method comprising:
pressure bonding a first metal foil to one of principal surfaces of a first insulating layer made of an uncured thermosetting resin;
forming a via hole in the first insulating layer while closing one of open ends of the via hole with the first metal foil;
forming a conductive via by filling the via hole with conductive paste;
pressure bonding a second metal foil to another one of the principal surfaces of the first insulating layer after the formation of the conductive via;
heating and thermally curing the first insulating layer after the pressure bonding of the second metal foil;
forming wiring by patterning the first metal foil and the second metal foil;
alternately stacking a plurality of the first insulating layers and second insulating layers made of an uncured thermosetting resin, after the formation of the wiring; and
heating and thermally curing the second insulating layers.

6. The method of manufacturing a multilayer board according to claim 5, wherein
the first insulating layer is heated and transformed into a semi-cured state in the pressure bonding the first metal foil, and
the first insulating layer is in the semi-cured state in the forming the via hole.

7. The method of manufacturing a multilayer board according to claim 6, the method further comprising:
exposing an inner surface of the via hole to a plasma atmosphere.

8. The method of manufacturing a multilayer board according to claim 5, wherein
by using a material containing a thermosetting resin as a material for the conductive paste, the conductive paste is thermally cured simultaneously with the thermal curing of the first insulating layer in the heating and thermally curing the first insulating layer.

9. The method of manufacturing a multilayer board according claim 8, wherein
the same material as the thermosetting resin of the first insulating layer is used as the thermosetting resin of the conductive paste.
